(19) United States
(12) Patent Application Publication
(10) Pub. No.: US 2004/0070522 A1
(43) Pub. Date: Apr. 15, 2004

(54) System and method for entering and interpreting a truncated alphamumerical keyboard entry

(76) Inventors: Kenzo Tsubai, Houston, TX (US); Linda Marroquin, Houston, TX (US)

Correspondence Address: Hayward A. Verdun, 609 Alder Ave NE, Bainbridge Island, WA, 98110, US

(21) Appl. No.: 10/272,542

(22) Filed: Oct. 15, 2002

(51) Int. Cl. H03M 11/00; H03K 17/94

(52) U.S. Cl. 341/22

(57) ABSTRACT

A keyboard layout for a one-handed keypad having fifteen alphabetic keys. Each key has a primary letter and a secondary letter. The primary letter is keyed by solely striking the key, while the secondary letter requires striking a secondary key first or simultaneously with the primary alphanumeric key. The layout placement minimizes finger travel and keystrokes to generate the most common letters and digraphs in any language.

### CROSS-REFERENCE TO RELATED APPLICATIONS

The current invention claims priority to provisional patent application No. ______ filed Oct. 15, 2001, entitled “SYSTEM AND METHOD FOR ENTERING AND INTERPRETING A TRUNCATED ALPHAMUMERICAL KEYBOARD ENTRY” by Kenzo Tsubai. The current invention incorporates U.S. Pat. No. 6,348,878, issued Feb. 19, 2002 to Tsubai and U.S. Pat. No. 5,793,312, issued Aug. 11, 1998 to Tsubai as if fully set forth herein.

### BACKGROUND OF THE INVENTION

1. Field of Invention

This invention relates to a one-handed data entry keyboard for use with a computer or like devices. Specifically, the invention describes a keyboard layout ergonomically designed to minimize finger movement based on a keyboard having less than 26 keys.

2. Related Art

As computers and like devices get smaller and more portable, it is desirable to have smaller than standard-sized keyboards. While the size of the electronics can be reduced to microscopic levels, and the display can be miniaturized and compensated by various methods including scrolling, the keyboard input remains a physical size limitation for the new generation of portable computers. Currently, this need is typically met by the “miniaturized keyboard”, in which the size of standard layout keys is reduced to achieve the smaller sizes desired. This miniaturization is typically of a standard QWERTY keyboard, so named for the first six keys on the top row. This approach has limited efficiency and a minimum level of miniaturization, since the size of users' hands and fingers remains constant. Thus, multiple keys are inadvertently stuck, or the user resorts to typing each key with the forefingers in a “hunt and peck” style.

A preferred approach to the problem is one-hand keyboards. These keyboards are smaller, since they require fewer keys than the minimum 72-key computer keyboard. By requiring fewer keys, one-hand keyboards can use full-sized keys.

Besides the benefit of miniaturized portable computers, one-hand keyboards are also useful in any application where one-hand use is preferred. Examples of such uses include CAD/CAM operators, who prefer to keep one hand on a “mouse” input device while the second hand remains on the keyboard; inventory recording devices which allow the user to handle items with one hand while inputting data with the other; and users with disabilities that allow the functional use of only one hand.

One type of one-hand keyboard is a “chording” keyboard. Just as simultaneous striking of keys on a keyboard for a musical instrument, such as a piano, result in a distinct musical chord, simultaneous striking of keys on a chording computer alphanumeric input keyboard result in various letters. These keyboards have a small number of keys, typically five. Thus striking the first two keys may result in the letter “A”, and striking the first, third and fifth key may result in the letter “Z”. These systems have coding systems that are difficult to learn and master. Besides having to learn chording codes for upper and lower case letters as well as numerals, the user must also remember less frequently used commands such as “Control”, “Alternate”, “Escape”, etc.

A one-hand keyboard of this type is described by Tsubai in U.S. Pat. No. 5,793,312. This keyboard has a plurality of primary alphanumeric keys, at least one secondary key, and a controller. When a primary alphanumeric key is depressed alone, its output signal results in the output of a primary letter, numeral or function. When a primary alphanumeric key is depressed simultaneously with one or more secondary keys, the controller interprets the multiple output signals and outputs a secondary letter, numeral or function. This keyboard operates very well, and is easy to learn the codes that are printed on top of each key as in a standard keyboard. However, a standard for the keyboard layout, based on ergonomic and heuristic principals, needs to be developed for use of such one-hand keyboards.

The speed, pace and rhythm of typing relies in part on “alternating keystrokes”. It is faster to hit a first key and a second key with different fingers (“alternating keystrokes”), rather than hitting the same key or different keys with the same finger (“redundant keystrokes”).

What is need is an easy to learn layout that minimizes finger movement and redundant keystrokes.

### SUMMARY OF THE INVENTION

Accordingly, the objectives of this invention are to provide, inter alia, a new and improved one-hand keyboard layout that is easy to learn, requires minimum finger movement, minimizes redundant keystrokes, allows fast data input, and includes all alphanumeric and functional keys found on a standard computer keyboard.

The objectives are addressed by the structure and use of the one-hand keyboard layout of the present invention. In one embodiment a nineteen key keypad, comprising fifteen primary and four secondary keys, is laid out in a manner that maximizes the number of character signals generated from located on a “home” position or by using single keystrokes. The fifteen primary alphanumeric keys are laid out in three rows with five keys in each row. The most commonly used letters in the English language are on keys in a primary mode (not requiring the simultaneous striking of one or more secondary function keys). Further, the most common two-letter combinations (digraphs) are on keys in the primary mode and proximate to one another. Other objects of the invention will become apparent from time to time throughout the specification hereinafter disclosed.

Additional embodiment of the present invention support key layouts of 8 or more keys with 1 or more control keys. Further embodiments are capable of producing the desire alpha-numeric character by one of simultaneous striking of multiple keys, the striking of keys in a predetermined sequential or the striking of the keys within a specified time parameter, i.e. in near proximity to each other, in any order as long as they result in the proper combination.

### BRIEF DESCRIPTION OF THE DRAWINGS

FIG. 1 depicts a layout of a one-handed 15 key right-handed keyboard of one embodiment of the present invention;

FIG. 2 depicts the keyboard of FIG. 1 without identifying numerals of one embodiment of the present invention;

FIG. 3 illustrates a flow diagram of the interpretation of the electronic signals generated by depressing of data entry keys of one embodiment of the present invention; and

FIG. 4 illustrates a flow diagram of the interpretation of the electronic signals generated by depressing of data entry keys of one embodiment of the present invention.

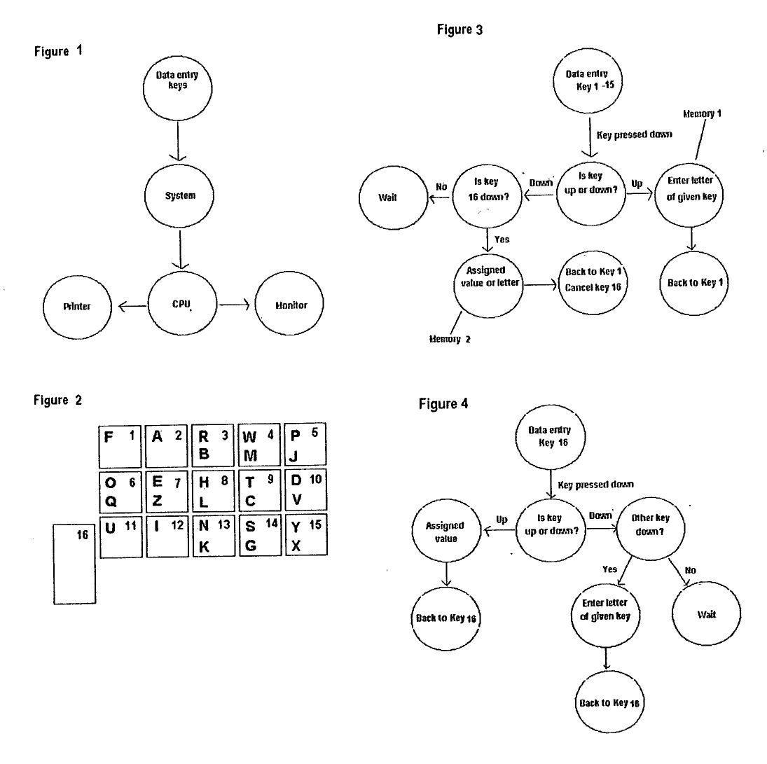

### DETAILED DESCRIPTION OF THE INVENTION

The Present invention (hereafter referred as System) relates to computer software, specifically used to enter alphabetical data into a computer or computer-like device. As miniaturization in computer and similar devices becomes more desirable, a miniaturization of the data entry key board from the standard 26 data entry keyboard (i.e. QWERTY keyboard) is desirable.

A computer software of the present invention is capable of recognizing electronic signals that are generated in accordance with depressing keys of the keyboard in a certain sequence, order or combination. The computer program translating the sequence, order or combination of signals into corresponding alpha-numeric characters.

The present invention is capable of being configured to recognize electronic signals generated by a keyboard of less than 26 characters and more than 8 characters.

The present invention is described as keyboard layout, depicted in block diagram form in FIG. 2. The inventive keyboard is designed for use with any device requiring an alpha-numeric input, such as a desktop computer, Personal Digital Assistant (PDA), laptop computer, computer aided drafting/manufacturing (CAD/CAM) device, inventory recorder, equipment controller or other device in which a one-handed keypad would benefit the user.

In one embodiment the present invention is directed to the layout of primary alphanumeric key 1 through primary alphanumeric key 15. Primary alphanumeric keys 1-15 are arranged in a top row of five, a middle row of five and a bottom row of five as shown in FIG. 2. Each of the five keys in each row are aligned with keys in the other two rows, to form five columns. While in this embodiment the arrangement of the five columns of primary keys are vertical and aligned, it is understood that these columns make alternatively be arranged slightly offset, diagonal, staggered, or any other roughly vertical alignment desired by the user/designer. Likewise, the three rows are depicted as straight horizontal rows. Alternatively, these rows may be slightly offset, diagonal, staggered, or any other roughly horizontal arrangement preferred by the user/designer.

All keyboard layouts are directed to a one-handed keyboard, depicted in the preferred embodiment and herein incorporated by reference as that described in the Tsubai U.S. Pat. No. 5,793,312. Alternate embodiments include any device having a keypad/keyboard with a reduced number of keys.

For example, pressing a single primary alphanumeric key (Keys 1-15) generates a signal for the primary letter depicted on the upper portion of the key. To generate a signal representing the secondary letter depicted in the lower portion of the key, the user presses at least one of the secondary keys (Keys 16-19) before pressing the primary alphanumeric key. Alternatively, the user may press a primary alphanumeric key and a secondary key concurrently, as described in the Tsubai U.S. Pat. No. 5,793,312, to generate a signal for a secondary letter. Functions other than alphabetic, such as symbols, may be entered by first pressing, and thereby changing the key functions from alphabetic to symbolic or function, by first pressing one or more of the secondary keys.

The primary letters of the primary alphanumeric keys are F, A, R, W, P, 0, E, H, T, D, U, I, N, S and Y. These letters account for 85.087% of alphabetic occurrences in words in the English language. The user is therefore able to type the vast majority of all words without striking any secondary keys, affording high typing speeds.

The frequency of single letters in the English language, in descending order, is shown in Table 1:

TABLE 1

| | Percentage of total | | Percentage of total |
|---|---|---|---|
| Letter | occurrences | Letter | occurrences |
| E | 12.702 | M | 2.406 |
| T | 9.056 | W | 2.360 |
| A | 8.167 | F | 2.228 |
| O | 7.507 | G | 2.015 |
| I | 6.996 | Y | 1.974 |
| N | 6.749 | P | 1.929 |
| S | 6.327 | B | 1.492 |
| H | 6.094 | V | 0.978 |
| R | 5.987 | K | 0.772 |
| D | 4.253 | J | 0.153 |
| L | 4.025 | X | 0.150 |
| C | 2.782 | Q | 0.095 |
| U | 2.758 | Z | 0.074 |

Source: H. Beker and F. Piper, Cipher Systems, Wiley-Interscience, 1982.

As is shown in Table 1, the most frequently used letters in the English language are E, T, A, 0, 1, N, S, H, R and D. Using nine of these letters, and substituting in the letter U for R, Professor August Dvorak developed the Dvorak keyboard in the early 20.sup.th Century. The letters A, O, E, U, I, D, H, T, N and S comprise the middle row of keys in the Dvorak keyboard, as these letters account for 70% of all occurrences of letters used in the English language.

The same letters found on the middle row of a Dvorak Simplified Keyboard (DSK) are shown in FIG. 5. While the letter R may be slightly more frequent in use than the letter U, keyboard layout 50 allows the keys for all five vowels to be struck by the index finger, and the five most common consonants are struck by the middle and ring fingers. Having the vowels all on primary alphanumeric keys struck with the same index finger is heuristically advantageous, since at least one vowel is found in every common English word. In addition, it is ergonomically advantageous to alternate keystrokes between fingers, avoiding having the same finger striking the same or different keys sequentially. Since most English words use consonants between vowels, this ensures a greater percentage of keystrokes alternating between fingers. Further, since the index, middle and ring fingers are the most nimble and strongest fingers, their frequent use keying vowels is ergonomically expedient.

In one embodiment of a 16 key keyboard the following keystrokes in a specific sequence, order or combination generates the subsequent alpha-numeric character, as illustrated in FIG. 2:

Letter F is entered at the moment key 1 is pressed and subsequently released;

Letter A is entered at the moment key 2 is pressed and subsequently released;

Letter R is entered at the moment key 3 is pressed and subsequently released;

Letter W is entered at the moment key 4 is pressed and subsequently released;

Letter P is entered at the moment key 5 is pressed and subsequently released;

Letter O is entered at the moment key 6 is pressed and subsequently released;

Letter E is entered at the moment key 7 is pressed and subsequently released;

Letter H is entered at the moment key 8 is pressed and subsequently released;

Letter T is entered at the moment key 9 is pressed and subsequently released;

Letter D is entered at the moment key 10 is pressed and subsequently released;

Letter U is entered at the moment key 11 is pressed and subsequently released;

Letter I is entered at the moment key 12 is pressed and subsequently released;

Letter N is entered at the moment key 13 is pressed and subsequently released;

Letter S is entered at the moment key 14 is pressed and subsequently released;

Letter Y is entered at the moment key 15 is pressed and subsequently released;

Letter B is entered at the moment key 3 and key 16 are pressed and subsequently released;

Letter M is entered at the moment key 4 and key 16 are pressed and subsequently released;

Letter J is entered at the moment key 5 and key 16 are pressed and subsequently released;

Letter Q is entered at the moment key 6 and key 16 are pressed and subsequently released;

Letter Z is entered at the moment key 7 and key 16 are pressed and subsequently released;

Letter L is entered at the moment key 8 and key 16 are pressed and subsequently released;

Letter C is entered at the moment key 9 and key 16 are pressed and subsequently released;

Letter V is entered at the moment key 10 and key 16 are pressed and subsequently released;

Letter K is entered at the moment key 13 and key 16 are pressed and subsequently released;

Letter G is entered at the moment key 14 and key 16 are pressed and subsequently released;

Letter X is entered at the moment key 15 and key 16 are pressed and subsequently released.

In this embodiment any multiple key combination programmed into the processor or computer is pressed simultaneously to produce the desired alpha-numeric character set.

In a second embodiment the keys are pressed in a specific combination to produce the desired alpha-numeric character set.

In a third embodiment the keys are pressed in a specific combination within a specified period of time, i.e. ½ second or longer, to produced the desired alpha-numeric character set.

In a fourth embodiment the keyboard layout contains less than 16 characters and generates all of the alpha-numeric characters of a standard QWERTY keyboard, are pressed in a specific combination to produce the desired alpha-numeric character set.

In a fifth embodiment the keyboard layout contains less than 16 characters and generates all of the alpha-numeric characters of a standard QWERTY keyboard, are pressed within a specified period of time, i.e. ½ second or longer, to produced the desired alpha-numeric character set.

In a sixth embodiment the keyboard layout contains less than 16 characters and generates all of the alpha-numeric characters of a standard QWERTY keyboard, are pressed are pressed in a specific combination to produce the desired alpha-numeric character set.

An additional embodiments of the present invention further include a software product. The software product capable of being executed on a general purpose computer, capable of configuring a general purpose computer or data processor and capable of configuring the computer or data processor to interpret keystrokes for non-standard QWERTY or Divoric keyboards. The software product is capable of interpreting the keystrokes from a character keyboard of 16 characters or a keyboard of greater than or equal to a 8 characters.

I claim:

1. A keyboard for a data entry system operable with one hand, comprising:
a keyboard, the keyboard comprising at least of one of 8, 9, 10, 11, 12, 13, 14, and 15 keys;
at least one control key, wherein each of the keyboard and control key is capable of generating at least one of a primary and secondary signal when depressed;
capturing keystrokes of the user and the resulting primary and secondary signals;
determining a specific alphanumeric character generated by at least one of the primary and secondary signals.

2. The keyboard as in claim 1, further including a second control key.

3. The keyboard as in claim 1, wherein the alphanumeric character generated is determined by the sequence of the keys depressed.

4. The keyboard as in claim 1, wherein the alphanumeric character generated is determined by the combination of the keys depressed.

5. The keyboard as in claim 1, wherein the alphanumeric character generated is determined by the keys depressed during a predetermined time interval of time.

6. The keyboard as in claim 5, wherein the alphanumeric character generated is determined by the sequence of the keys depressed during the predetermined time interval.

7. The keyboard as in claim 5, wherein the alphanumeric character generated is determined by the combination of the keys depressed during the predetermined time interval.

8. A keyboard for a data entry system operable with one hand, comprising:
a keyboard, the keyboard comprising at least of one of 8, 9, 10, 11, 12, 13, 14, and 15 keys;
at least one control key, wherein each of the keyboard and control key is capable of generating at least one of a primary and secondary signal when depressed;
means for capturing keystrokes of the user and the resulting primary and secondary signals;
means for determining a specific alphanumeric character generated by at least one of the primary and secondary signals.
